(19) United States
(12) Patent Application Publication
(10) Pub. No.: US 2007/0107873 A1
(43) Pub. Date: May 17, 2007

(54) Water-Cooling Head and Method for making the same

(76) Inventor: Yu-Huang Peng, Chung-Ho City (TW)

Correspondence Address: HDSL, 4331 STEVENS BATTLE LANE, FAIRFAX, VA, 22033, US

(21) Appl. No.: 11/530,872

(22) Filed: Sep. 11, 2006

(30) Foreign Application Priority Data
Nov. 11, 2005 (TW) 094139650

(51) Int. Cl. H05K 7/20

(52) U.S. Cl. 165/80.4; 165/907; 361/699

(57) ABSTRACT

A water-cooling head and a method for making the same. A first cover and a second cover form a water-cooling head. An intake pipe and a drainpipe extend from both ends of the first cover. A plurality of heat-conducting particles is fixedly provided inside of the second cover and irregularly stacks to form a flowing path microstructure. The outside of the second cover has a contacting surface for absorbing the heat generated by the heat source and conducting the heat to the heat-conducting particles. When the cooling liquid enters the water-cooling head via the intake pipe, the flowing path microstructure disturbs the flow of the cooling liquid to prolong the staying time of the cooling liquid within the water-cooling head. In this way, the cooling liquid can be sufficiently heat-exchanged with the heat-conducting particles and then drains out from the drainpipe.

### BACKGROUND OF THE INVENTION

1. Field of the Invention

The present invention relates to a water-cooling heat-dissipating structure and a method for making the same, and in particular to a water-cooling head suitable for electronic elements and a method for making the same.

2. Description of Prior Art

The operation of any electrical apparatus will inevitably generate excessive heat due to the low efficiency and friction. Especially, the products made by modern technological industries tend to be developed with increasing precision. For example, integrated circuits or personal electronic products are gradually miniaturized in size but the heat generated by those products is increasing. Especially, since the arithmetic efficiency of the computer improves continuously, the total heat generated by the computer itself increases accordingly. Further, the heat-generating source in the computer is not limited to CPU only, other high-speed devices such as chip model, graph processing unit, dynamic memory and hard disc also generate considerable amount of heat. Therefore, in order to make the computer to operate normally under an allowable working temperature, it is necessary to use additional heat-dissipating devices to reduce the unfavorable effect of the heat on the operation of computer elements.

The fan is a kind of heat-dissipating device, which is simple, convenient and most wildly used. The rotation of fan blades causes the air around the heat-generating element to flow rapidly, so that the heat generated by the heat-generating element can be rapidly taken away, thereby to achieve the heat-dissipating effect. However, the actual heat-dissipating effect of the fan falls short of expectation because the heat-dissipating area cannot satisfy its heat-conducting efficiency. Thereafter, a plurality of heat-dissipating pieces are attached to the heat-generating element to increase the heat-dissipating area and thus the heat-conducting efficiency, with the airflow generated by the fan, the heat generated by the heat source can be taken away. However, the amount of the airflow generated by the fan is so limited that the heat-dissipating effect of the fan cannot be efficiently improved. Therefore, in conventional art, several sets of heat-dissipating fans are connected in series to increase the total airflow, however, such a measure is difficult to implement because of the restriction of space. If the rotation speed of the motor is raised to increase the amount of airflow, it becomes more difficult to manufacture the motor. In addition, there is still an upper limit in increasing the rotation speed of the motor, and the larger rotation speed of the motor will generate unfavorable noise, vibration and heat, which further restrict the implementation thereof.

According to the above, the increase of the efficiency of the fan is limited so that the heat-dissipating effect and the range for reducing temperature cannot be improved to a large extent. In order to satisfy the demand for the heat dissipation of electronic elements operated in high speed, it is necessary to find out other solutions. Therefore, a conventional art discloses a water-cooling heat-dissipating device, in which a water-cooling head is adhered onto a heat-generating element such as CPU or disk driver. A motor is used to draw out the cooling liquid from a tank and introduce the cooling liquid into the water-cooling head. After the cooling liquid is heat-exchanged with the heat absorbed by the water-cooling head from the heat-generating element, the cooling liquid flows to a heat-dissipating module via the water-cooling head. After being cooled, the cooling liquid returns to the tank. With the circulation of the cooling liquid, the heat-dissipating effect can be facilitated. As a result, the temperature of the heat-generating element can be reduced, thereby to smooth the operation of the whole system.

Although the cooling liquid can be heat-exchanged with the heat source via the water-cooling head, which produces a heat-dissipating effect superior to that caused by airflow, in the above-mentioned water-cooling head, the heat-absorbing surface of the water-cooling head is only concentrated in the same place, so that only a portion of the cooling liquid entering the water-cooling head can be heat-exchanged with the heat-absorbing surface. Further, the staying time of the cooling liquid within the water-cooling head is too short, so that the cooling liquid is immediately guided out via another pipe without absorbing enough heat. Therefore, another conventional art discloses a water-cooling heat-dissipating structure, as shown in FIG. 1, in which the inside of the water-cooling head 101 is fixedly provided with a plurality of heat-dissipating pieces 102 to form a plurality of one-way flowing paths. After the cooling liquid is introduced into the water-cooling head 101, the plurality of heat-dissipating pieces can increase the heat-dissipating area. When the cooling liquid passes through the plurality of one-way flowing paths, the cooling liquid is heat-exchanged with the heat-dissipating pieces, thereby to improve the heat-dissipating effect.

In the above-mentioned heat-dissipating structure, the heat-dissipating pieces can increase the heat-dissipating area and the plurality of flowing paths formed by the heat-dissipating pieces can guide the flowing direction of the cooling liquid within the water-cooling head, so that the contacting area between the cooling liquid and the heat-dissipating pieces is substantially increased to enhance the heat exchange, however, the space of the one-way flowing path is not fine enough, so that the cooling liquid still passes through the one-way flowing paths rapidly. As a result, the staying time of the cooling liquid still cannot be substantially increased, so that the cooling liquid cannot absorb enough heat from the heat-dissipating pieces to efficiently improve the heat-dissipating effect. Therefore, there is still plenty of room for improvement.

### SUMMARY OF THE INVENTION

In view of the above drawbacks, the object of the present invention is to provide a water-cooling head and a method for making the same. Fine flowing paths formed by irregularly stacking heat-conducting particles can disturb the flow of the cooling liquid, thereby to substantially increase the staying time of the cooling liquid within the water-cooling head. Further, by means of the heat exchange with the contacting area formed by the heat-conducting particles, the cooling liquid can substantially absorb the heat from the heat-generating element. As a result, the heat-dissipating effect can be efficiently improved.

### BRIEF DESCRIPTION OF THE DRAWINGS

FIG. 1 is an exploded perspective view showing a conventional water-cooling head;

FIG. 2 is a top view showing the second cover of the water-cooling head of the present invention;

FIG. 3 is an exploded perspective view of the present invention;

FIG. 4 is a schematic view showing the manufacturing process of the flowing path microstructure of the present invention;

FIG. 5 is a schematic view showing the forming process of the flowing path microstructure of the present invention;

FIG. 6 is a schematic view showing the flowing path microstructure of the present invention;

FIG. 7 is a schematic view showing the operation of the flowing path microstructure of the present invention;

FIG. 8 is a flowchart showing the manufacturing method of the present invention;

FIG. 9 is a schematic view showing the flowing path microstructure according to another embodiment of the present invention;

FIG. 10 is a schematic view showing the structure of parallel heat-dissipating pieces of the present invention;

FIG. 11 is a schematic view showing the structure of a heat-conducting pillar of the present invention; and

FIG. 12 is a schematic view showing the flowing path microstructure according to a further embodiment of the present invention.

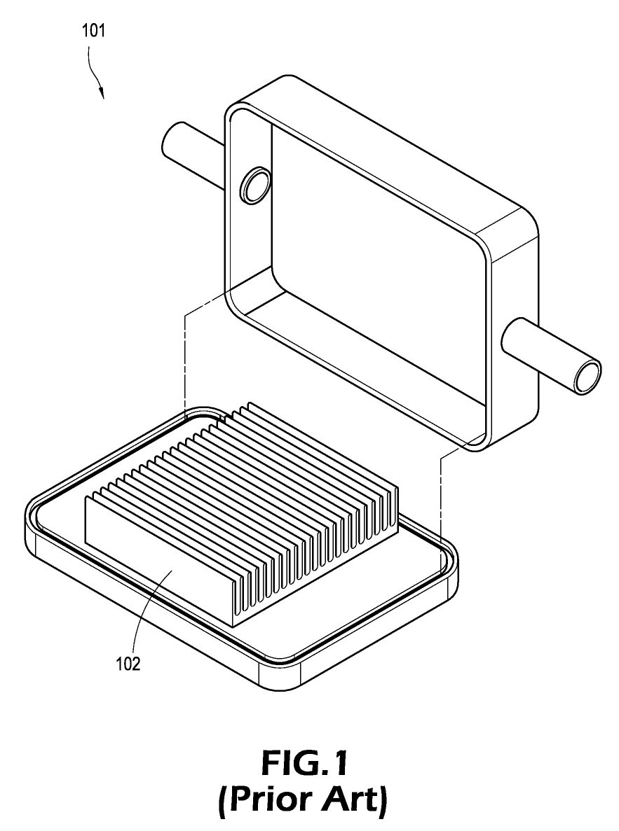

### DETAILED DESCRIPTION OF THE INVENTION

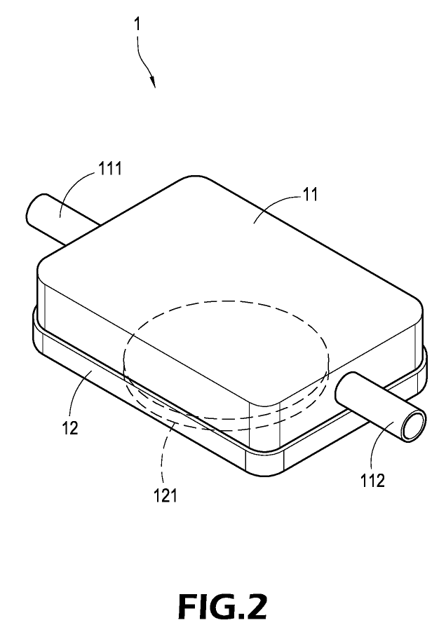

With reference to FIG. 2, it can be seen that, the water-cooling head 1 of the present invention is formed into a hollow sealed box by a first cover 11 and a second cover 12. The profile of the water-cooling head 1 can be suitably changed according to different demands. The first cover 11 and the second cover 12 of the present embodiment can be formed into a rectangular body (but not limited thereto) and made of suitable materials such as metal or ceramic. The first cover 11 and the second cover 12 are connected by means of welding, riveting or binding. In addition, an intake pipe 111 and a drainpipe 112 extend outwardly (also upwardly) from the surfaces of left and right sides of the first cover 11, respectively, thereby to provide the cooling liquid with pipes for entering and draining from the water-cooling head 1. Further, the bottom surface of the second cover 12 is provided with a contacting surface 121 thereon for contacting with a heat-generating source (not shown).

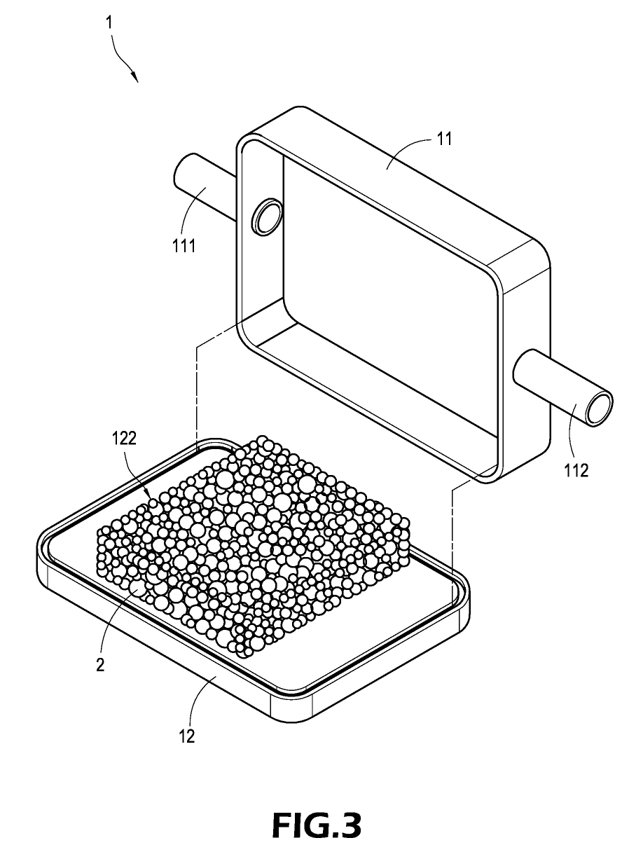

With reference to FIG. 3, it is an exploded perspective view of the present invention. The inside of the second cover 12 is further provided with a flowing path microstructure 122. The flowing path microstructure 122 is formed by irregularly stacking a plurality of heat-conducting particles 2. The gaps among the particles are formed into fine flowing paths. The heat-conducting particles 2 are formed into circular, square or other irregular shape having different dimensions. Further, the plurality of heat-conducting particles 3 is made of heat-conducting materials such as metal or ceramic.

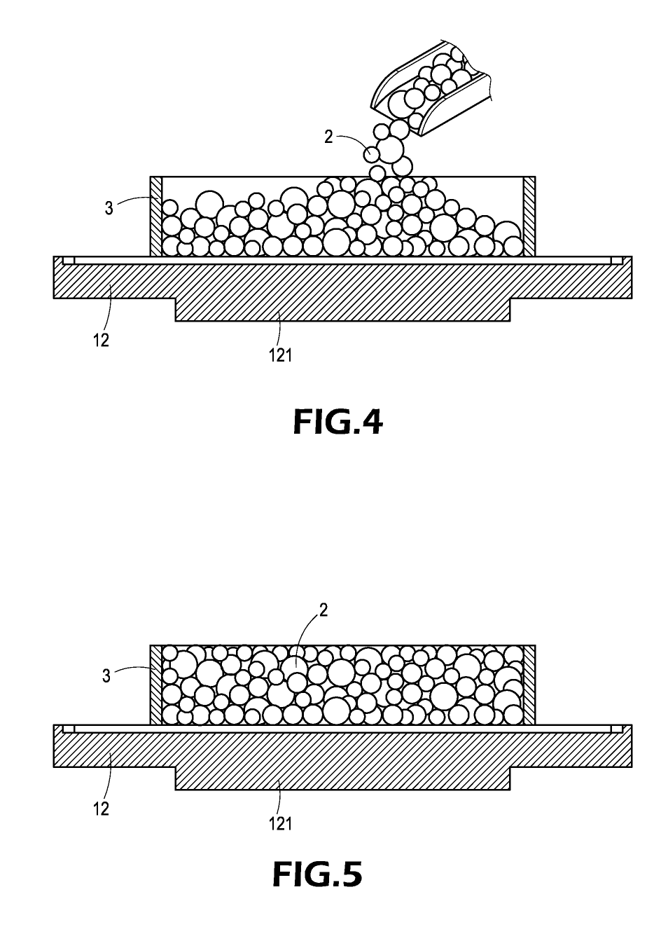

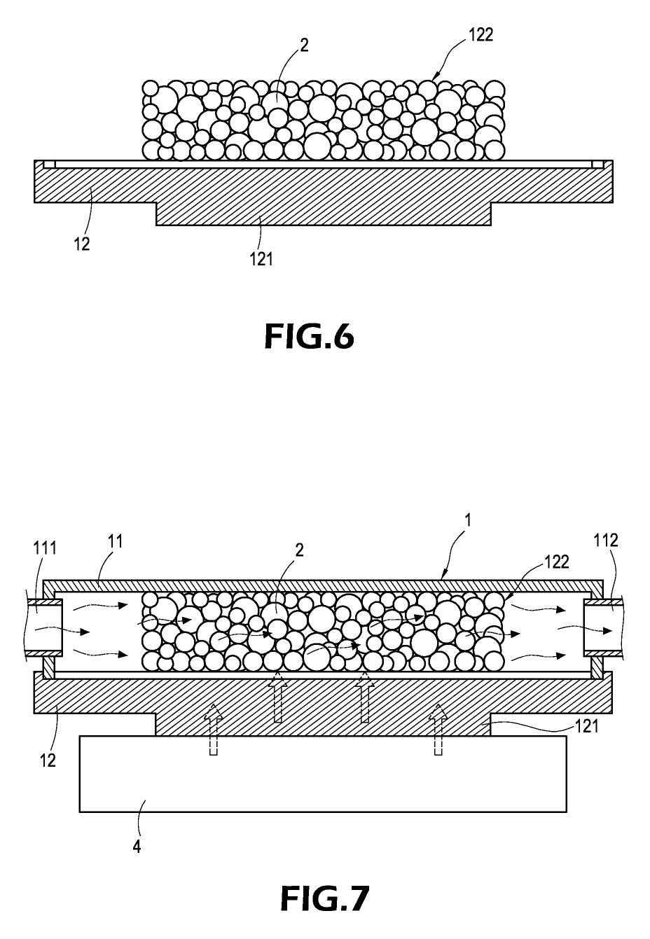

With reference to FIG. 4 first, the method for making the water-cooling head 1 is described as follows. A mold 3 is disposed into a predetermined position inside the second cover 12. Then, the plurality of heat-conducting particles 2 which are previously made and formed are poured into the mold 3 and irregularly stacks to completely fill the mold 3. With reference to FIG. 5, after the heat-conducting particles 2 have completely filled the mold 3, the plurality of heat-conducting particles 2 within the mold 3 are tightly combined with each other and fixedly provided on the surface of the second cover 12 by means of high-temperature sintering. After being taken out of the mold 3, the plurality of heat-conducting particles 2 can be formed into the flowing path microstructure 122 as shown in FIG. 6. Next, with reference to FIG. 7, the first cover 11 and the second cover 12 are finally connected by means of welding, riveting or binding, thereby to finish the water-cooling head 1.

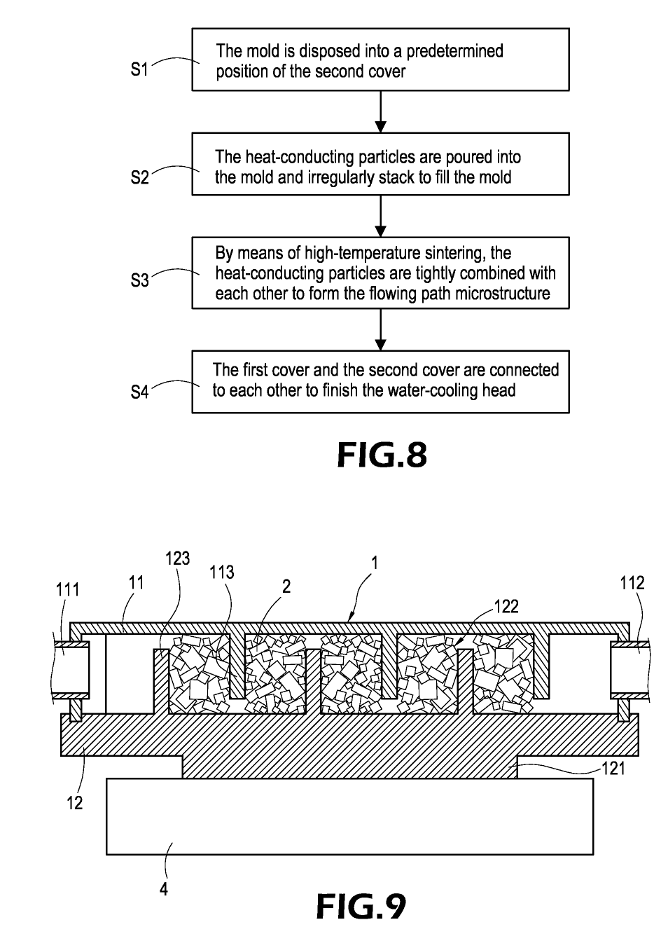

With reference to FIG. 8, the flowchart illustrates the method for making the water-cooling head 1. First, the mold 3 is disposed into a predetermined position of the second cover 12 (S1). Then, the heat-conducting particles 2 are poured into the mold 3 and irregularly stack to fill the mold 3 (S2). Gaps are formed among each heat-conducting particles 2. By means of high-temperature sintering, the heat-conducting particles are tightly combined with each other to form the flowing path microstructure 122 (S3). Finally, the first cover 11 and the second cover 12 are connected to each other by means of welding, riveting or binding, thereby to finish the water-cooling head 1 (S4).

With reference to FIG. 7 again, when the water-cooling head 1 is adhered onto the heat-generating element 1, the heat generated by the heat-generating element 4 can be absorbed by the contacting surface 121. Then, the heat is conducted to the heat-conducting particles 2 inside the water-cooling head 2. After the cooling liquid enters the water-cooling head 1 via the intake pipe 111, the flowing path microstructure 122 disturbs the flow of the cooling liquid to substantially prolong the staying time of the cooling liquid within the water-cooling head 1. As a result, the cooling liquid is heat-exchanged with the plurality of heat-conducting particles 2 to absorb enough heat. Finally, the cooling liquid is drained out via the drainpipe 112. In this way, the heat-dissipating operation is completed.

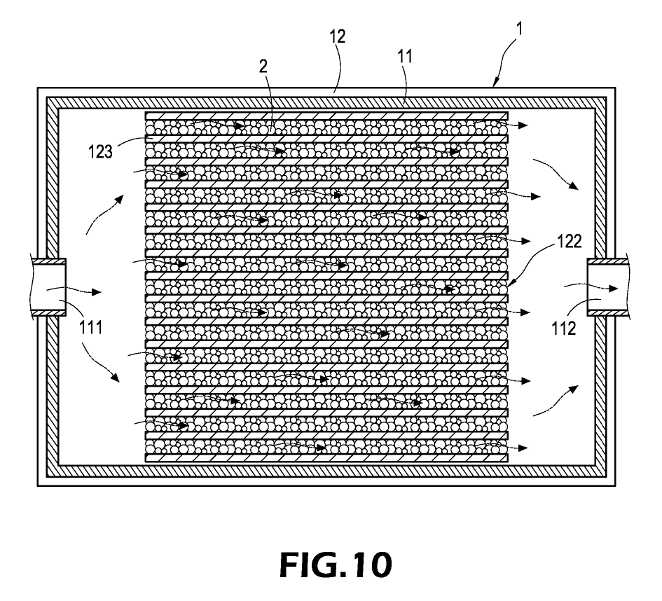

With reference to FIG. 9, it shows another embodiment of the resent invention. The first cover 11 and the second cover 12 are provided with a plurality of heat-dissipating pieces (fins) 113, 123 perpendicular to the surface thereof, respectively. The heat-dissipating pieces 113, 123 are alternatively arranged to form a plurality of intervals. Those intervals are communicated with each other to form circuitous one-way flowing paths. Thereafter, the plurality of heat-conducting particles 2 are disposed into the intervals to form the flowing path microstructure 122. Therefore, when the contacting surface 121 of the water-cooling head 1 is adhered to the heat-generating element 4, the heat is absorbed by the contacting surface 121, conducted to the heat-dissipating pieces 113, 123 and dissipated onto the heat-conducting particles 2. After the cooling liquid enters the one-way flowing paths via the intake pipe 111, the flowing path microstructure 122 disturbs the flow of the cooling liquid and the plurality of heat-dissipating pieces 113, 123 and the heat-conducting particles 2 are heat-exchanged, so that the cooling liquid can take the heat away and drain out via the drainpipe 112. In this way, the heat-dissipating operation can be achieved. Alternatively, as shown in FIG. 10, only the plurality of heat-dissipating pieces 123 are vertically provided on the surface of the second cover 12 to form a plurality of parallel flowing paths. Then, the flowing path microstructure 122 formed by the heat-conducting particles 2 are disposed into the flowing path.

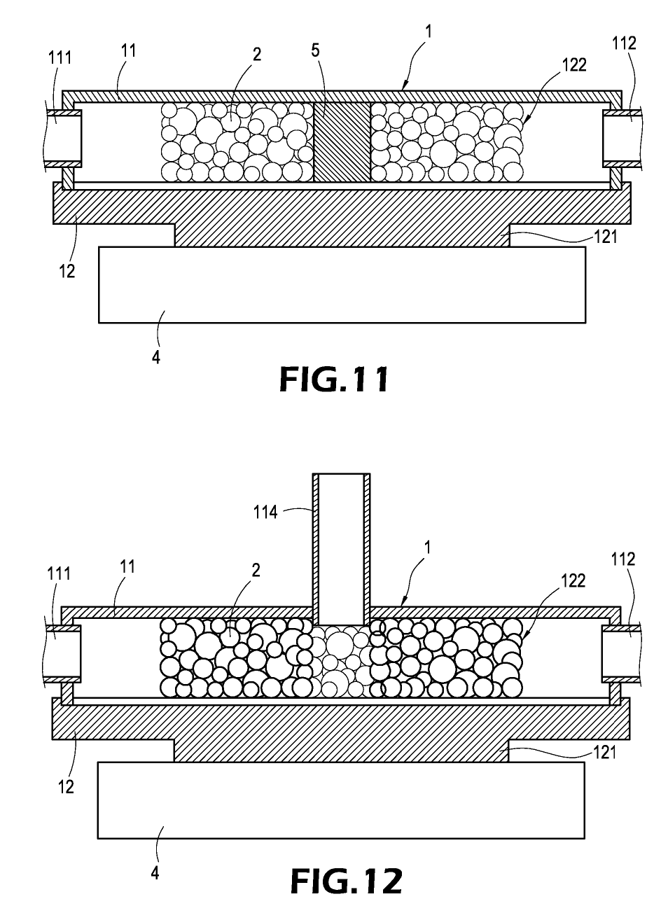

Alternatively, at a position of the second cover 12 in which the flowing path microstructure 122 is to be provided, as shown in FIG. 11, at least one (one shown in the figure) heat-conducting post 5 is previously provided to erect upright on the inside surface of the second cover 12. Then, the flowing path microstructure 122 formed by the heat-conducting particles 2 are provided around the heat-conducting post 5.

With reference to FIG. 12, it shows another embodiment of the present invention. On the first cover 11, a third pipe 114 is provided to be opposite to the contacting surface 121. At the same time, a hole is provided at a position in which the microstructure 122 within the water-cooling head 1 is opposite to the third pipe 114. Therefore, after the cooling liquid is introduced via the third pipe 114, it directly flows through the contacting surface 121 adhered to the heat-generating element 4 and is heat-exchanged with the contacting surface 121. After this, the cooling liquid drains out via the flowing path microstructure 122 and the drainpipe 112. Therefore, the number of the pipes is not limited.

Although the present invention has been described with reference to the foregoing preferred embodiments, it will be understood that the invention is not limited to the details thereof Various equivalent variations and modifications can still be occurred to those skilled in this art in view of the teachings of the present invention. Thus, all such variations and equivalent modifications are also embraced within the scope of the invention as defined in the appended claims.

What is claimed is:

1. A water-cooling head structure comprising:
a water-cooling head being a hollow box and having at least one intake pipe and at least one drainpipe; and
a plurality of heat-conducting particles provided within the water-cooling head and irregularly stacking to form a flowing path microstructure.

2. The water-cooling head structure according to claim 1, wherein a bottom surface of the water-cooling head has a contacting surface for adhering to a heat-generating source.

3. The water-cooling head structure according to claim 1, wherein the water-cooling head includes a first cover and a second cover.

4. The water-cooling head structure according to claim 3, wherein the second cover further has a plurality of heat-dissipating pieces.

5. The water-cooling head structure according to claim 4, wherein the heat-dissipating pieces are arranged to be parallel to each other.

6. The water-cooling head structure according to claim 3, wherein the second cover further has at least one heat-conducting post.

7. The water-cooling head structure according to claim 3, wherein both of the first cover and the second cover have a plurality of heat-dissipating pieces.

8. The water-cooling head structure according to claim 7, wherein the heat-dissipating pieces of the first cover and the second cover are alternatively arranged.

9. A method for making a water-cooling head, comprising the steps of:
a) disposing a mold into a predetermined position of a second cover;
b) filling a plurality of heat-conducting particles into the mold;
c) sintering the heat-conducting particles to combine them together to form a flowing path microstructure; and
d) connecting a first cover having at least one pipe with the second cover.

10. The method according to claim 9, wherein the first cover and the second cover are connected by means of any one of welding, riveting and binding.
